(19) United States
(12) Patent Application Publication
(10) Pub. No.: US 2009/0072239 A1
(43) Pub. Date: Mar. 19, 2009

(54) Gallium oxide single crystal composite, process for producing the same, and process for producing nitride semiconductor film utilizing gallium oxide single crystal composite

(76) Inventors: Shigeo Oohira, Shizuoka (JP); Yasushi Nanishi, Shiga (JP); Tsutomu Araki, Shiga (JP); Tomohiro Yamaguchi, Bremen (DE)

Correspondence Address: EDWARDS ANGELL PALMER & DODGE LLP, P.O. BOX 55874, BOSTON, MA, 02205, US

(21) Appl. No.: 11/579,863

(22) PCT Filed: May 11, 2005
(86) PCT No.: PCT/JP05/08593

§ 371 Date: Nov. 24, 2008

(30) Foreign Application Priority Data
May 13, 2004 (JP) 2004-143535

(51) Int. Cl. H01L 29/205

(52) U.S. Cl. 257/76; 257/E29.091

(57) ABSTRACT

Provided are: a gallium oxide single crystal composite, which can provide, for example, upon a crystal growth of a nitride semiconductor, a high-quality cubic crystal in which mixing of a hexagonal crystal is reduced to thereby realize dominant growth of a cubic crystal over hexagonal crystal, and which can be utilized as a substrate particularly suitable for epitaxial growth of cubic GaN; a process for producing the same; and a process for producing a nitride semiconductor film. The gallium oxide single crystal composite has a gallium nitride layer formed of cubic gallium nitride on a surface of the gallium oxide single crystal; the process for producing the gallium oxide single crystal composite includes subjecting the surface of gallium oxide single crystal to nitriding treatment using ECR plasma or RF plasma to form the gallium nitride layer formed of cubic gallium nitride on the surface of the gallium oxide single crystal; and further, the process for producing the nitride semiconductor film includes growing the nitride semiconductor film on the surface of the gallium oxide single crystal composite by an RF-MBE method.

### TECHNICAL FIELD

The present invention relates to a gallium oxide single crystal composite having a gallium nitride layer formed of cubic gallium nitride (GaN) on a surface of a gallium oxide (Ga₂O₃) single crystal, to a process for producing the gallium oxide single crystal composite, and to a process for producing a nitride semiconductor film using the gallium oxide single crystal composite. The gallium oxide single crystal composite can be used as a substrate used for forming a group III-V nitride semiconductor formed of gallium nitride (GaN), aluminum nitride (AlN), indium nitride (InN), a mixed crystal thereof, or the like, and is particularly preferably used for formation of cubic GaN.

### BACKGROUND ART

A group III-V nitride semiconductor formed of gallium nitride (GaN), aluminum nitride (AlN), indium nitride (InN), a mixed crystal thereof, or the like is a direct transmission-type and may have a band gap capable of being designed from 0.7 eV to 6.2 eV. Thus, various applications of the group III-V nitride semiconductor as a material for a light emitting device covering a visible light region are expected, and a light emitting diode (LED) of a blue, green, or white color, a violet LED, and the like have already been commercially available.

A crystallographic feature of the nitride semiconductor is that the nitride semiconductor has two crystal structures of a hexagonal wurtzite structure stable in a thermal equilibrium state and a metastable cubic zinc blende structure. In general, a hexagonal crystal is widely used as a device. Meanwhile, a cubic crystal has higher symmetry as a crystal than that of the hexagonal crystal, and thus, has no anisotropy of a band, causes little scattering with respect to a carrier, expected of high mobility of the carrier, has an excellent doping efficiency, and the like. Thus, the cubic crystal is considered to be advantageous for applications of an optical or electronic device for improving luminous efficiency due to cavity of a semiconductor laser using a cleavage or reduction of a piezoelectric field, and a development regarding crystal growth of the group III-V nitride semiconductor film having a cubic structure has been advanced. Of those, a cubic crystal of GaN has particularly attracted attention for its advanced applications such as a highly efficient blue light emitting diode, a blue semiconductor laser, and a high temperature operating two-dimensional electron gas FET.

As a substrate used for epitaxial growth of cubic GaN, Si, GaAs, GaP, 3C—SiC, and the like have been heretofore used (see Table 9.3 in p. 180 of Non-patent Document 1). Cubic GaN is generally obtained through epitaxial growth, on a (001) plane of a crystal, of such a material having a cubic structure, and a cubic crystal is considered to be obtained through the growth of GaN on a (100) plane of a GaAs substrate or an Si substrate, for example. Meanwhile, a hexagonal crystal is obtained through growth of GaN on a (111) plane of those substrates (see p. 168 and 169 of Non-patent Document 1).

However, Si has merits of realizing a large diameter wafer and low cost, but has problems in degraded high-frequency properties, interface reactivity with GaN, and extensive mismatch in lattice constant with GaN. Further, GaAs has better high-frequency properties than those of Si but extensive lattice mismatch as Si, and thus, a crystal of a device level is hardly formed. In addition, As or P is not suitable as a material to be actively used hereafter in consideration of environmental problems. Further, SiC has high thermal conductivity and is excellent as a power device substrate, but requires further improvements for providing high quality, high purity, high resistance, low cost, large diameter, and the like.

Meanwhile, simple use of the (001) plane as that of the above-mentioned cubic crystal of the substrate assures no growth of cubic GaN, and special attention must be paid during initial growth, or mixing of a hexagonal crystal as a energetically stable phase becomes significant. For example, the cubic crystal gradually changes into the hexagonal crystal through partial etching of a GaAs substrate during an initial growth process due to heat decomposition of the GaAs substrate, to thereby lose interface smoothness, generate many stacking faults from a part without smoothness, and to increase the stacking faults. Reasons for the mixing of hexagonal GaN and degraded crystallinity of cubic GaN may include formation of a GaN (111) facet plane due to slight degradation of smoothness on a GaN growth surface and formation of a GaAs (111) facet plane due to loss of smoothness at an interface between the substrate and the growth plane by plasma nitrogen damaging the substrate. Another reason therefor may be amorphization of a buffer layer due to extensive lattice mismatch between the substrate and a layer under epitaxial growth.

In this way, a high quality cubic GaN thin film is hardly obtained on a crystal growth plane, and a quality of a cubic epitaxial film to be obtained is not sufficient compared with that of a hexagonal epitaxial film. Thus, for improvement in quality of a nitride semiconductor film having a cubic structure, a substrate suitable for epitaxial growth of cubic GaN must be developed. Ultimately, a bulk GaN single crystal substrate may be used as a substrate for epitaxial growth of a GaN film. However, the bulk GaN single crystal has a large N₂ vapor pressure and a high melting point during formation, so the bulk GaN single crystal substrate is hardly formed by a normal melting method. Thus, the bulk GaN single crystal substrate requires high temperature and high pressure conditions for single crystal growth. Accordingly, there arise problems such as a complex crystal formation apparatus and high cost. There are formation methods such as a liquid phase epitaxy (LPE) method and an Na flux method, but those methods each have difficulties in control of a crystal structure and therefore have problems in quality.

In view of the circumstances described above, there are proposed various methods and techniques such as: a method involving forming a GaN buffer layer on a GaAs substrate by introducing a group V raw material gas and a group III raw material gas, and forming cubic GaN having reduced mixing ratio of hexagonal GaN on the GaN buffer layer through a predetermined heat treatment step and introduction of raw material gases (see Patent Document 1); a method involving realizing a high quality group III nitride semiconductor crystal such as cubic GaN by growing an InGaAsN single crystal thin film, a group III nitride single crystal thin film, and a group III nitride semiconductor crystal on a GaAs single crystal substrate by a predetermined method (see Patent Document 2); a technique of forming a good quality GaN thin film having very little faults by using a main plane for GaN growth formed of a single crystal belonging to a specific crystal system and by using a substrate formed of garnet or the like such that a misfit ratio to a structural period of a GaN single crystal becomes a predetermined value (see Patent Document 3); a method for epitaxially growing a cubic GaN-based semiconductor on a tungsten single crystal substrate having a (001) plane as a main plane (see Patent Document 4); a method involving growing good quality cubic GaN with easy cleavage by growing a crystal of AlAs on a GaAs substrate, reacting a surface of the AlAs layer with nitrogen to convert a surface layer of the AlAs layer to an AlN film, and growing a crystal of GaN on the AlN film (see Patent Document 5); a technique of forming a smooth cubic nitride semiconductor layer on a surface nitrided semiconductor layer by forming a cubic nitride semiconductor layer formed of GaN on a GaAs substrate through a cubic semiconductor layer containing aluminum (see Patent Document 6); and a light emitting device having a GaN-based compound semiconductor thin film formed on a gallium oxide substrate by an MOCVD method.

As described above, various methods regarding crystal growth of a nitride semiconductor film having a cubic structure have been proposed, but the methods are each based on the fact that no substrate realizing lattice matching in epitaxial growth of a cubic nitride semiconductor is present. Thus, a development of a substrate realizing lattice matching with a cubic nitride semiconductor and capable of allowing dominant growth of a cubic crystal over a hexagonal crystal is desired.

### Patent Document 1: JP 2001-15442 A

### Patent Document 2: JP 2003-142404 A

### Patent Document 3: JP 07-288231 A

### Patent Document 4: JP 10-126009 A

### Patent Document 5: JP 10-251100 A

### Patent Document 6: JP 11-54438 A

### Patent Document 7: JP 2004-56098 A

Non-patent Document 1: Akasaki, Isamu. (1999). Group III Nitride Semiconductor. Baifukan Co., Ltd.

### DISCLOSURE OF THE INVENTION

### Problems to be Solved by the Invention

The inventors of the present invention have conducted intensive studies on a novel substrate replacing a substrate conventionally used, that is, a substrate capable of reducing lattice mismatch with respect to a cubic nitride semiconductor as much as possible. The inventors of the present invention have focused on gallium oxide (Ga₂O₃) which can provide a single crystal with relative ease, and have found that cubic gallium nitride is formed on the surface of a gallium oxide single crystal by subjecting a surface of the gallium oxide single crystal to optimized nitriding treatment. The inventors of the present invention have acquired a finding that a gallium oxide single crystal composite having cubic gallium nitride on the surface of the gallium oxide single crystal is suitable for epitaxial growth of a cubic nitride semiconductor, in particular, for epitaxial growth of cubic GaN, and have completed the present invention.

An object of the present invention is therefore to provide a gallium oxide single crystal composite having a gallium nitride layer formed of cubic gallium nitride (GaN) on its surface, that is, a gallium oxide single crystal composite which can provide a high quality cubic crystal in which mixing of a hexagonal crystal can be reduced and a cubic crystal is grown dominantly over the hexagonal crystal upon crystal growth of a group III-V nitride semiconductor formed of gallium nitride (GaN), aluminum nitride (AlN), indium nitride (InN), a mixed crystal thereof, or the like, for example, and in particular, a gallium oxide single crystal composite which can be used as a substrate suitable for epitaxial growth of cubic GaN.

Another object of the present invention is to provide a method for providing a gallium oxide single crystal composite which requires advantageous conditions compared with conditions required for obtaining a bulk gallium nitride single crystal, for example, and which can provide a gallium oxide single crystal composite having a gallium nitride layer formed of cubic gallium nitride (GaN) on its surface by simple means.

Still another object of the present invention is to provide a process for producing a nitride semiconductor film capable of allowing dominant growth of a cubic crystal over a hexagonal crystal and capable of producing a high quality cubic nitride semiconductor film.

### Means for Solving the Problems

Therefore, according to one aspect of the present invention, there is provided a gallium oxide single crystal composite, characterized by including a gallium nitride layer formed of cubic gallium nitride (GaN) on a surface of a gallium oxide (Ga₂O₃) single crystal.

Further, according to another aspect of the present invention, there is provided a process for producing a gallium oxide single crystal composite, characterized by including subjecting a surface of a gallium oxide (Ga₂O₃) single crystal to nitriding treatment employing ECR plasma or RF plasma to form a gallium nitride layer formed of cubic gallium nitride (GaN) on the surface of the gallium oxide single crystal.

Further, according to another aspect of the present invention, there is provided a process for producing a nitride semiconductor film, characterized by including growing a nitride semiconductor film on the surface of the gallium oxide single crystal composite described above by an RF-MBE method, for instance.

The gallium oxide single crystal composite of the present invention refers to a composite of a gallium oxide single crystal having a gallium nitride layer formed of cubic gallium nitride (GaN) on a surface of the gallium oxide (Ga₂O₃) single crystal, and cubic gallium nitride.

The gallium nitride layer has only to be a gallium nitride layer substantially formed of cubic gallium nitride. The gallium nitride layer substantially formed of cubic gallium nitride has only to have a spotted reflection high-energy electron diffraction (RHEED) pattern of a surface of the gallium oxide single crystal composite and have cubic gallium nitride formed as shown in Embodiments to be described below, for example. Other substances in an amount providing substantially no effects on the RHEED pattern may be included.

The gallium nitride layer of the present invention is preferably formed of cubic gallium nitride in substantially <100> orientation from viewpoints of device properties, functional properties, and the like of a nitride semiconductor upon growth of the nitride semiconductor on the surface of the gallium oxide single crystal composite of the present invention, for example. As well as the above-mentioned gallium nitride layer substantially formed of cubic gallium nitride, cubic gallium nitride in substantially <100> orientation has only to have a spotted reflection high-energy electron diffraction (RHEED) pattern of a surface of the gallium oxide single crystal composite and have cubic gallium nitride in <100> orientation formed, for example.

In the present invention, the gallium nitride layer has a thickness of 1 nm or more, and preferably within a range of 1 nm to 10 nm. A thickness of the gallium nitride layer of less than 1 nm hardly provides a cubic nitride semiconductor required for the case where the gallium oxide single crystal composite of the present invention is used as a crystal growth substrate for a nitride semiconductor such as gallium nitride (GaN), aluminum nitride (AlN), or indium nitride (InN), and a buffer layer must be formed separately. In contrast, a thickness of the gallium nitride layer of more than 10 nm saturates effects of growing a cubic crystal of the nitride semiconductor as described above and improving quality of the cubic crystal to be obtained, extends a treatment time for forming the gallium nitride layer, and increases cost, for example. Note that the thickness of the gallium nitride layer may be calculated from an in-depth analysis by a secondary ion mass spectrometry (SIMS) or an X-ray photoelectron spectroscopy (XPS), for example, or calculated from sectional observation with an electron microscope.

The gallium nitride layer of the present invention may be formed by subjecting the surface of the gallium oxide single crystal to nitriding treatment, and is preferably formed through nitriding treatment employing electron cyclotron resonance (ECR) plasma or nitriding treatment employing radio frequency (RF) plasma. The nitriding treatment employing ECR plasma or RF plasma allows formation of a gallium nitride layer through modification of the surface of the gallium oxide single crystal to cubic gallium nitride. This case advantageously allows low temperature treatment of 800° C. or lower, which is more suitable for formation of cubic gallium nitride as a metastable phase. The gallium nitride layer is preferably formed through nitriding treatment employing ECR plasma from the viewpoint of providing highly-excited plasma at a higher plasma density.

In the nitriding treatment employing ECR plasma or RF plasma, a nitrogen (N₂) gas, an ammonia (NH₃) gas, a mixed gas prepared by adding hydrogen (H₂) to nitrogen (N₂), or the like may be used as a nitrogen source, and a nitrogen (N₂) gas is preferably used. In the nitriding treatment employing ECR plasma or RF plasma, a temperature of the gallium oxide single crystal to be used as a substrate varies depending on the kind of plasma source or nitrogen source. However, in the nitriding treatment employing ECR plasma and using a nitrogen gas as a nitrogen source, for example, the temperature thereof is preferably within a range of 500 to 800° C. A temperature thereof of lower than 500° C. results in insufficient nitriding through a reaction between nitrogen and the substrate, and a temperature thereof of higher than 800° C. facilitates growth of hexagonal gallium nitride than cubic gallium nitride.

The nitriding treatment employing ECR plasma or RF plasma may be performed by using a general apparatus. The nitriding treatment employing ECR plasma, for example, may be performed by using a chamber for an ECR-molecular beam epitaxy (MBE) apparatus. Specific conditions for the nitriding treatment vary depending on the nitrogen source to be used, but in the case where the nitrogen gas is used, for example, excited plasma is generated by applying a magnetic field (875 G) of 2.45 GHz to molecular nitrogen (N₂) to expose the surface of the gallium oxide single crystal. The conditions in this case include: a microwave power of 100 to 300 W; a nitrogen flow rate of 8 to 20 sccm (standard cc/min); and a treatment time of 30 to 120 min.

In the present invention, the surface of the gallium oxide single crystal forming the gallium nitride layer is preferably a (100) plane of the gallium oxide single crystal. The (100) plane of the gallium oxide single crystal is a plane parallel to a growth direction of the gallium oxide single crystal, and thus the gallium oxide single crystal is liable to cleave on the (100) plane. This is suitable for formation of an optical resonator mirror used for laser emission of a semiconductor laser or the like on a cleavage plane of a GaN crystal, for example.

In the present invention, the surface of the gallium oxide single crystal is preferably polished and then subjected to the nitriding treatment described above. Polishing of the surface of the gallium oxide single crystal can reduce fault formation in cubic gallium nitride formed on the surface of the gallium oxide single crystal through nitriding treatment and formation of a hexagonal crystal structure. An example of polishing means to be used in this case is means generally used in mirror finish of an LSI silicon wafer, that is, chemical mechanical polishing (CMP) combining a mechanical removal action with particles such as abrasive grains and a chemical solution removal action with a working fluid.

The shape, size, and the like of the gallium oxide single crystal of the present invention are not particularly limited as long as the gallium nitride layer formed of cubic gallium nitride can be formed on its surface. The gallium oxide single crystal may be designed freely in accordance with an application of the gallium oxide single crystal composite to be obtained.

Means for obtaining the gallium oxide single crystal is not particularly limited, and means generally used for obtaining a bulk gallium oxide single crystal may be employed, for example. Preferably, the gallium oxide single crystal is produced by a floating zone (FZ) method by using a gallium oxide sintered product obtained by firing gallium oxide powder. The gallium oxide single crystal obtained by the floating zone method is obtained by melting a raw material without using a vessel and growing the gallium oxide single crystal, is capable of preventing contamination by impurities as much as possible, and can be obtained as a gallium oxide single crystal with excellent crystallinity. Thus, the gallium oxide single crystal obtained by the floating zone method is advantageous in that a risk of affecting crystallinity or the like of the cubic gallium nitride to be formed on the surface of the gallium oxide single crystal can be reduced as much as possible. Further, the gallium oxide single crystal obtained by the floating zone method is advantageous in that the gallium oxide single crystal can be obtained at low cost because the gallium oxide powder to be used as a starting material is available with relative ease. Specific conditions for obtaining the gallium oxide single crystal by the floating zone method may employ general conditions for single crystal growth.

As described above, the gallium oxide single crystal composite of the present invention can be produced by, for example, subjecting the surface of the gallium oxide (Ga₂O₃) single crystal to nitriding treatment employing ECR plasma or RF plasma, and forming the gallium nitride layer formed of cubic gallium nitride (GaN) on the surface of the gallium oxide single crystal. In this case, polishing treatment for polishing the surface of the gallium oxide single crystal is preferably performed before the nitriding treatment for the reasons described above, and the surface of the gallium oxide single crystal is preferably a (100) plane of the gallium oxide single crystal for the reasons described above.

In the present invention, the surface of the gallium oxide single crystal is preferably subjected to surface treatment, and thermal cleaning treatment for heating the surface-treated gallium oxide single crystal is preferably performed before the nitriding treatment. The surface treatment is performed before the nitriding treatment, to thereby remove an oxide film formed on the surface of the gallium oxide single crystal. The thermal cleaning treatment is performed, to thereby remove unstable oxides excluding pure gallium oxide (Ga₂O₃).

The surface treatment preferably involves one or both of hydrogen fluoride (HF) treatment using HF which is also used for oxide treatment of Si, and etchant treatment using a solution prepared by mixing H₂O, H₂SO₄, and H₂O₂ in a volume ratio of H₂O:H₂SO₄:H₂O₂=1:(3 to 4):1 which is also used for washing of a GaAs substrate. More preferably, the surface of the gallium oxide single crystal is subjected to HF treatment and then to etchant treatment.

The thermal cleaning of the surface-treated gallium oxide single crystal is preferably performed through heat treatment of the gallium oxide single crystal at a temperature of 750 to 850° C. and preferably 800° C. for a heating time of 20 to 60 min.

In the present invention, before the gallium oxide single crystal is subjected to surface treatment, the gallium oxide single crystal is preferably immersed in acetone for washing and immersed in methanol for washing.

The application of the gallium oxide single crystal composite of the present invention is not particularly limited, but the gallium oxide single crystal composite may be used as a nitride semiconductor substrate used forming a group III-V nitride semiconductor formed of gallium nitride (GaN), aluminum nitride (AlN), indium nitride (InN), a mixed crystal thereof, or the like, for example. For formation of the nitride semiconductor, a nitride semiconductor film may be grown on the surface of the gallium oxide single crystal composite by a method such as a metal organic chemical vapor deposition (MOCVD) method or an molecular beam epitaxial (MBE) method, but is preferably grown by the MBE method, in particular. For growth of a cubic GaN film, for example, an optimal growth temperature for GaN is 600 to 800° C. for the MBE method, which is lower than the optimal growth temperature therefor for the MOCVD method of 1,000 to 1,100° C. Thus, the MBE method is suitable for growth of the cubic GaN film as a metastable phase.

For growth of the nitride semiconductor film by the MBE method, a solid of Ga, Al, In, or the like is preferably used as a group III source. A nitrogen (N₂) gas, an ammonia (NH₃) gas, a mixed gas prepared by adding hydrogen (H₂) to nitrogen (N₂), or the like may be used as a nitrogen source, and a nitrogen (N₂) gas is preferably used.

In the case where the MBE method is used, the nitride semiconductor is more preferably grown on the surface of the gallium oxide single crystal composite by an RF-MBE method, in particular. For nitriding treatment of the surface of the gallium oxide single crystal, ECR plasma having a higher plasma density is preferably used. However, for obtaining the nitride semiconductor film, an excessively high plasma density may damage a film to be grown, and thus the RF-MBE method is more suitable.

The process for producing a nitride semiconductor film including growing the nitride semiconductor film on the surface of the gallium oxide single crystal by the RF-MBE method may be conducted with an MBE apparatus employing an RF plasma cell, for example. Production conditions in this case may vary depending on the nitrogen source or group III source to be used. However, for growth of the gallium nitride film by using a nitrogen (N₂) gas and solid Ga, for example, excited plasma is generated by applying a high-frequency magnetic field (875 G) with a frequency of 13.56 MHz to molecular nitrogen (N₂). Film formation conditions include: a temperature of the gallium oxide single crystal composite to be used as a substrate of 600 to 800° C.; a nitrogen gas flow rate of 2 to 10 sccm (standard cc/min); an RF power of 200 to 400 W; and a treatment time of 30 to 120 min.

### EFFECTS OF THE INVENTION

The gallium oxide single crystal composite of the present invention has the gallium nitride layer formed of cubic gallium nitride on the surface of the gallium oxide single crystal. Thus, in the case where the gallium oxide single crystal composite is used as a nitride semiconductor substrate formed of a group III-V nitride semiconductor formed of gallium nitride (GaN), aluminum nitride (AlN), indium nitride (InN), a mixed crystal thereof, or the like, a high quality cubic nitride semiconductor film in which mixing of a hexagonal crystal can be reduced and a cubic crystal is grown dominantly over the hexagonal crystal can be obtained. The phrase “a cubic crystal is grown dominantly over the hexagonal crystal” indicates that abundance of the cubic crystal is higher than that of the hexagonal crystal. The gallium oxide single crystal composite of the present invention has the gallium nitride layer formed of cubic gallium nitride on its surface, to thereby reduce lattice mismatch at an interface with the substrate upon crystal growth of cubic gallium nitride (GaN) as much as possible and allow epitaxial growth of a high quality cubic GaN film, in particular.

The process for producing a gallium oxide single crystal composite of the present invention requires advantageous conditions compared with conditions required for obtaining a bulk gallium nitride single crystal, for example, and is advantageous in that the gallium oxide single crystal composite can be obtained at low cost because the gallium nitride layer formed of cubic gallium nitride can be formed on the surface of the gallium oxide single crystal by simple means and the gallium oxide single crystal available with relative ease is used.

The process for producing a nitride semiconductor film of the present invention provides the nitride semiconductor film by using the gallium oxide single crystal composite. Thus, the method can provide a high quality cubic nitride semiconductor film in which mixing of the hexagonal crystal can be reduced and the cubic crystal is grown dominantly over the hexagonal crystal. The gallium oxide single crystal composite may be used for epitaxial growth of the cubic nitride semiconductor without separately forming a buffer layer because the gallium oxide single crystal is provided with the gallium nitride layer formed of cubic gallium nitride on its surface, and a production process may be simplified.

### BRIEF DESCRIPTION OF THE DRAWINGS

FIG. 1 shows reflection high-energy electron diffraction (RHEED) patterns of a surface of a gallium oxide single crystal composite according to Example 1 of the present invention, where Parts (A) and (B) show two typical patterns obtained.

FIG. 2 shows reflection high-energy electron diffraction (RHEED) patterns of a surface of a gallium oxide single crystal according to Example 2 of the present invention, where Parts (a-1) and (a-2) show RHEED patterns of a gallium oxide single crystal obtained through chemical mechanical polishing, and Parts (b-1) and (b-2) show RHEED patterns of a gallium oxide single crystal obtained through hand polishing.

FIG. 3 shows reflection high-energy electron diffraction (RHEED) patterns of a surface of a gallium oxide single crystal composite according to Example 2 of the present invention, where Parts (a) and (b) show two typical patterns obtained.

FIG. 4 shows AFM measurement photographs of a gallium nitride layer of the gallium oxide single crystal composite according to Example 2, where Part (a) shows a surface roughness distribution (two-dimensional) of 6 μm×6 μm, and Part (b) shows a three-dimensional distribution of Part (a).

FIG. 5 shows reflection high-energy electron diffraction (RHEED) patterns of a surface of a gallium nitride film grown on the surface of the gallium oxide single crystal composite according to Example of the present invention, where Parts (A) and (B) show two typical patterns obtained.

FIG. 6 shows results of X-ray diffraction measurement of the gallium nitride film grown on the surface of the gallium oxide single crystal composite according to Example of the present invention by an ω-2θ method.

FIG. 7 shows results of analysis of the gallium nitride film grown on the surface of the gallium oxide single crystal composite according to Example of the present invention by an in-plane X-ray diffraction method.

FIG. 8 shows a Φ scan profile of a cubic GaN (200) peak obtained by an in-plane X-ray diffraction method.

FIG. 9 shows a Raman spectrum of a substrate (i.e., gallium oxide single crystal composite) of the gallium oxide single crystal composite having the gallium nitride film formed on its surface according to Example of the present invention.

FIG. 10 shows a Raman spectrum of a gallium nitride film of the gallium oxide single crystal composite having the gallium nitride film formed on its surface according to Example of the present invention.

### BEST MODE FOR CARRYING OUT THE INVENTION

Hereinafter, the present invention will be described more specifically based on Examples.

### Example 1

### Production of Gallium Oxide Single Crystal

First, gallium oxide powder having a purity of 99.99% was sealed in a rubber tube, and was molded into a rod at a gravitational pressure of 450 MPa. The resultant was placed in an electric furnace and fired at 1,600° C. for 20 hours in atmospheric air, to thereby obtain a gallium oxide sintered product. The rod obtained after firing had a size of about 9 mmΦ×40 mm.

Next, growth of a gallium oxide single crystal was performed by using this gallium oxide sintered product as a raw material rod by an optical floating zone (FZ) method. A double ellipsoid-type infrared heating furnace (SS-10W, manufactured by ASGAL Informatik GmbH) was used for growth of the single crystal.

To be specific, the gallium oxide sintered product obtained above was provided on an upper shaft as a raw material rod, and the gallium oxide single crystal was provided on a lower shaft as a seed crystal. A crystal growth atmosphere was a dry air atmosphere containing an oxygen gas and a nitrogen gas in a volume ratio of O₂/N₂=20.0 (vol %), and a flow rate of the dry air to be supplied to a reaction tube was 500 ml/min. Ends of the raw material rod and the seed crystal were moved to a furnace center for melt contact, and a zone melting operation was performed at a revolution speed of the raw material rod and the seed crystal of 20 rpm and a crystal growth speed of 5 mm/h. In this way, a gallium oxide single crystal with 10 mm diameter×80 mm length was produced.

### Production of Gallium Oxide Single Crystal Composite

The gallium oxide single crystal obtained above was cut out to a size of 8 mm length×8 mm width×2 mm thickness, and was subjected to polishing treatment with a (100) plane of the gallium oxide single crystal serving as a surface. Then, the gallium oxide single crystal was immersed in acetone for 10 min for washing treatment and immersed in methanol for 10 min for washing treatment. The washed gallium oxide single crystal was immersed in hydrofluoric acid for 10 min for HF treatment (as surface treatment), and immersed in a solution (of 60° C.) prepared by mixing H₂O, H₂SO₄, and H₂O₂ in a volume ratio of H₂O:H₂SO₄:H₂O₂=1:4:1 for 5 min for etchant treatment (as surface treatment).

The surface-treated gallium oxide single crystal was set on a sample holder of an ECR-MBE apparatus, and the gallium oxide single crystal was heated to about 800° C. and held for 30 min for thermal cleaning. Then, the (100) plane of the gallium oxide single crystal was subjected to nitriding treatment by using a nitrogen (N₂) gas as a nitrogen source and using ECR plasma. Conditions for the nitriding treatment employing ECR plasma include a microwave power of 200 W, a nitrogen flow rate of 10 sccm, a temperature (i.e., substrate temperature) of the gallium oxide single crystal of 750° C., and a treatment time of 60 min.

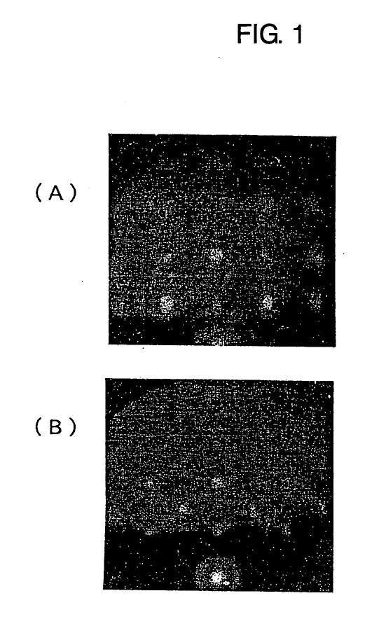

FIG. 1 shows reflection high-energy electron diffraction (RHEED) patterns of the surface of a gallium oxide single crystal composite obtained through nitriding treatment. As shown in FIG. 1, two spotted patterns of (A) and (B) were observed, and analysis of the patterns of (A) and (B) indicate <100> orientation. That is, the patterns indicate that the gallium nitride layer formed of cubic gallium nitride was formed on the surface of the nitriding-treated gallium oxide single crystal.

### Example 2

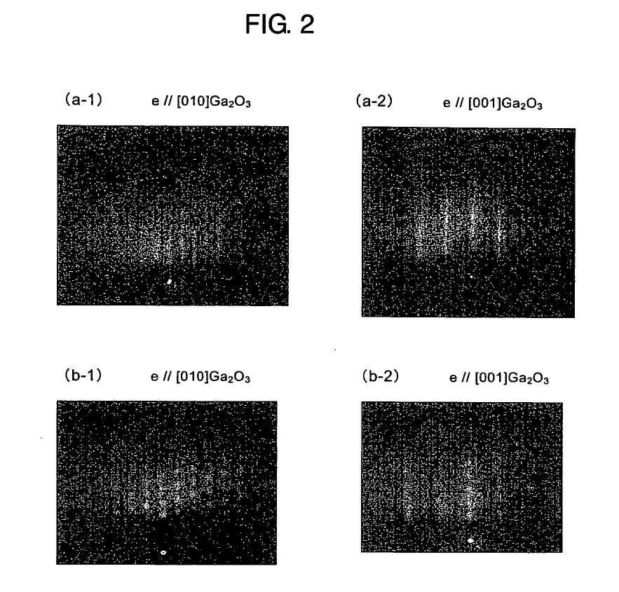

A gallium oxide single crystal was produced and cut out to a size of 8 mm length×8 mm width×2 mm thickness in the same manner as in Example 1. The (100) plane of the gallium oxide single crystal was subjected to polishing treatment through chemical mechanical polishing (CMP) employing colloidal silica. FIG. 2 shows reflection high-energy electron diffraction (RHEED) patterns of the surface of the CMP-treated gallium oxide single crystal. FIG. 2(a-1) shows an RHEED pattern obtained upon injection of an electron beam from a [010] direction of the gallium oxide single crystal, and FIG. 2(a-2) shows an RHEED pattern obtained upon injection of an electron beam from a [001] direction of the gallium oxide single crystal. For reference, FIG. 2(b) shows RHEED patterns of the case where the (100) plane of the gallium oxide single crystal was subjected to polishing treatment through hand polishing with SiC emery paper and buff. FIG. 2(b-1) shows an RHEED pattern obtained upon injection of an electron beam from the [010] direction of the gallium oxide single crystal, and FIG. 2(b-2) shows an RHEED pattern obtained upon injection of an electron beam from the [001] direction of the gallium oxide single crystal. In comparison of the patterns, the gallium oxide single crystal subjected to hand polishing provides spotted RHEED patterns, but the gallium oxide single crystal subjected to CMP treatment provides streaked RHEED patterns. Thus, the comparison indicates that a smooth gallium oxide single crystal surface was obtained through CMP treatment.

The CMP-treated gallium oxide single crystal was subjected to washing treatments using acetone and methanol, HF treatment (as surface treatment), and etchant treatment (as surface treatment) in the same manner as in Example 1. Then, the (100) plane of the gallium oxide single crystal was subjected to nitriding treatment in the same manner as in Example 1 by using the ECR-MBE apparatus, to thereby form a gallium nitride layer.

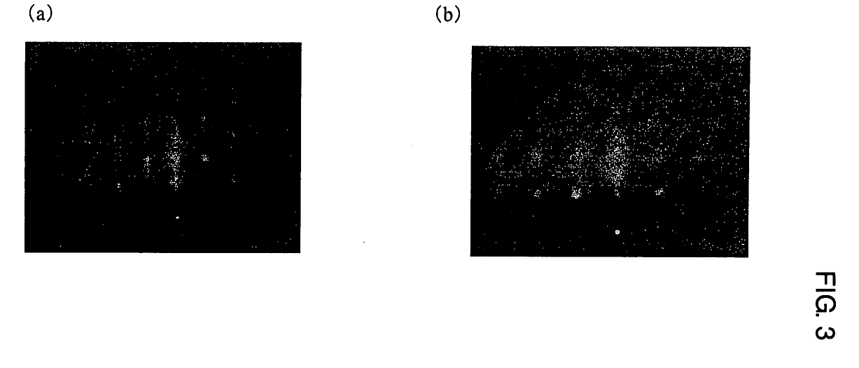

FIG. 3 shows reflection high-energy electron diffraction (RHEED) patterns of the surface of the nitriding-treated gallium oxide single crystal obtained above upon injection of an electron beam from a [111] direction of gallium nitride. As (a) and (b) indicate in FIG. 3, spotted patterns were observed, and analysis of the patterns indicate gallium nitride in <100> orientation. That is, the patterns indicate that the gallium nitride layer formed of cubic gallium nitride was formed on the surface of the nitriding-treated gallium oxide single crystal.

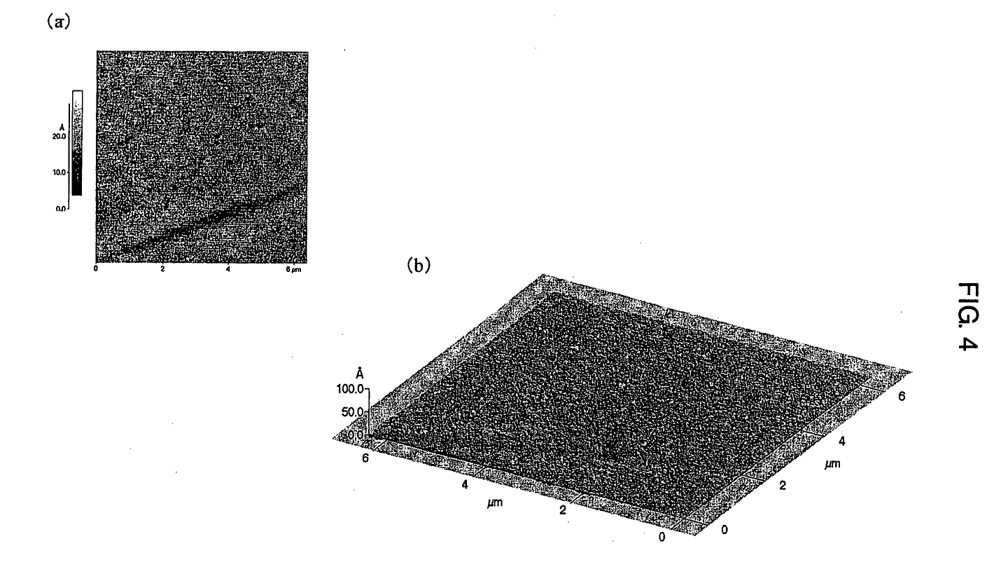

Measurement of surface roughness of the nitrided gallium layer with an atomic force microscope (AFM) confirmed that the surface was very smooth with a surface roughness of 0.2 nm. FIG. 4 shows the results of the AFM measurement. FIG. 4(a) shows a surface roughness distribution (which is two-dimensional) of 6 μm×6 μm, and FIG. 4(b) shows a three-dimensional distribution of (a). The results of the AFM measurement and the RHEED patterns indicate that cubic gallium nitride was uniformly formed on the surface of the gallium oxide single crystal through nitriding treatment employing ECR plasma of the gallium oxide single crystal subjected to smoothing at an atomic level.

### Example 3

### Production of Gallium Nitride Film

The gallium oxide single crystal composite obtained in Example 1 was used for growth of a gallium nitride film.

The gallium oxide single crystal composite was set in an RF-MBE apparatus, and a gallium nitride film with a thickness of about 500 nm was grown on the surface of the gallium oxide single crystal composite by using a nitrogen (N₂) gas as a nitrogen source and solid Ga as a Ga source under the conditions including a temperature (i.e., substrate temperature) of the gallium oxide single crystal composite of 880° C., a nitrogen gas flow rate of 2 sccm, an RF power of 330 W, and a film formation time of 60 min.

### Reflection High-Energy Electron Diffraction

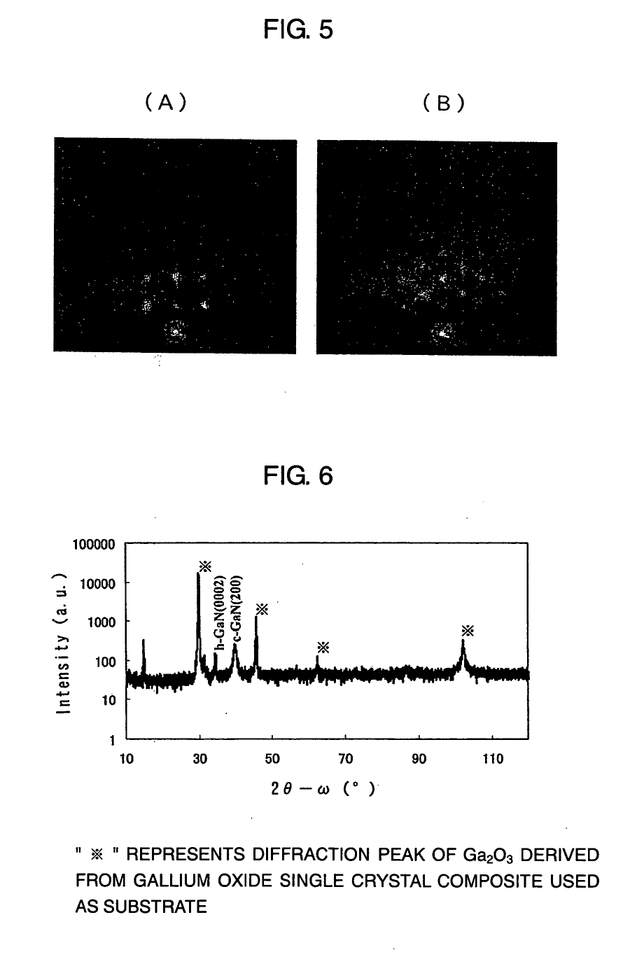

FIG. 5 shows reflection high-energy electron diffraction (RHEED) patterns of the surface of the gallium nitride film grown on the surface of the gallium oxide single crystal composite as described above. As shown in FIG. 5, two typical patterns of (A) and (B) were observed, and analysis of a crystal structure resulted in a cubic structure. Thus, the patterns indicate that the gallium nitride film grown on the surface of the gallium oxide single crystal composite was cubic GaN.

### X-Ray Diffraction

FIG. 6 shows results of X-ray diffraction measurement of the gallium nitride film grown on the surface of the gallium oxide single crystal composite by an ω-2θ method. In FIG. 6, a diffraction peak of cubic c-GaN(200) and a diffraction peak of hexagonal h-GaN(0002) were observed, but the intensity of the diffraction peak of cubic c-GaN(200) was stronger. Note that peaks marked by “” in FIG. 6 represent diffraction peaks of Ga₂O₃ derived from the gallium oxide single crystal composite used as a substrate.

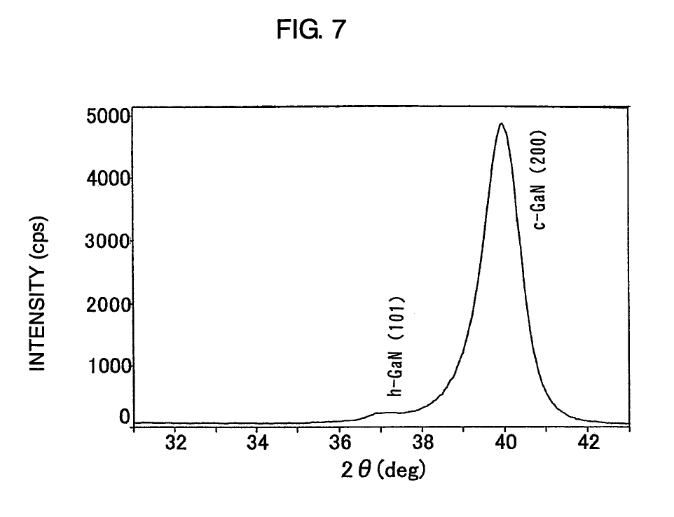

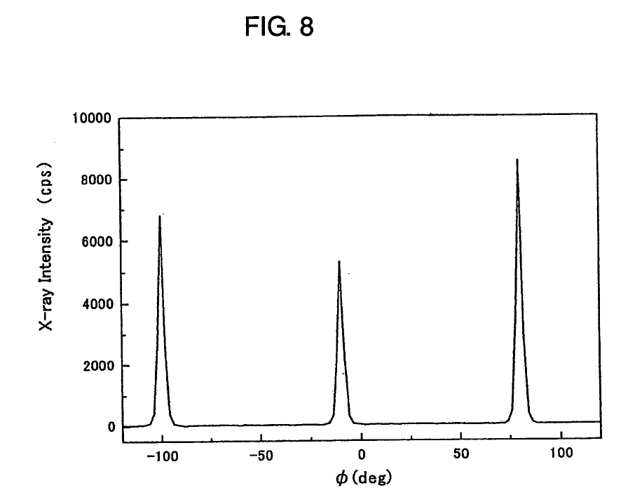

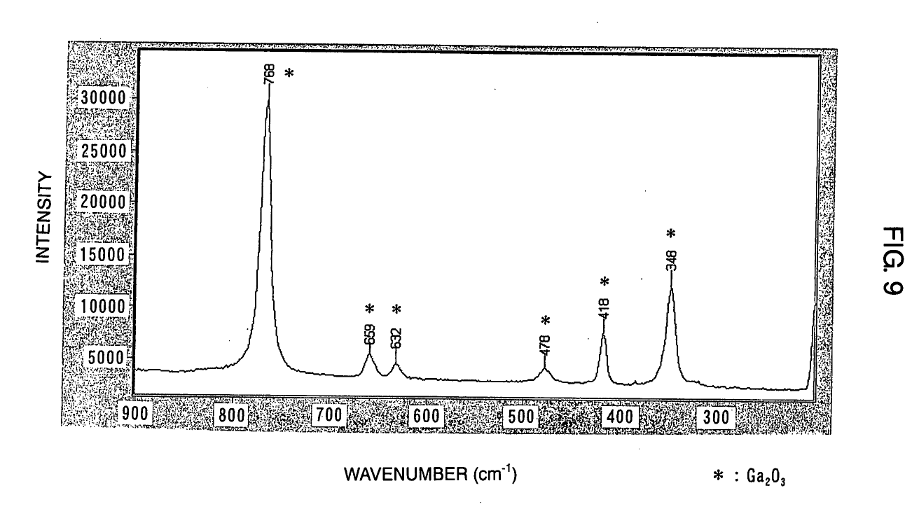

FIG. 7 shows results of crystal structural analysis of the gallium nitride film, which was subjected to X-ray diffraction measurement by the ω-2θ method, by an in-plane X-ray diffraction method. The in-plane X-ray diffraction method is means for obtaining structural information of a sample surface, and is advantageous in that information of a crystal plane aligned in a direction perpendicular to a sample plane can be obtained with a relatively high detection intensity. Measurement was performed by using ATX-G manufactured by Rigaku Corporation under conditions including a voltage of 50 kV, a current of 300 mA, an X-ray injection angle of 0.4°, and a scanning step of 0.04°. The results of FIG. 7 indicate that a strong diffraction peak of cubic c-GaN(200) and a weak diffraction peak of hexagonal h-GaN (101) were detected. An in-plane rotational profile [Φ scan of GaN(200)] of a cubic c-GaN(200) plane was measured for the gallium nitride film subjected to measurement by the in-plane X-ray diffraction method. FIG. 8 shows the results. The results of FIG. 8 indicate that an in-plane spacing is detected at 90° spacing. Thus, the gallium nitride film formed on the surface of the gallium oxide single crystal composite had a cubic structure and was oriented dominantly in a specific direction in the plane.

### Raman Spectrum Measurement

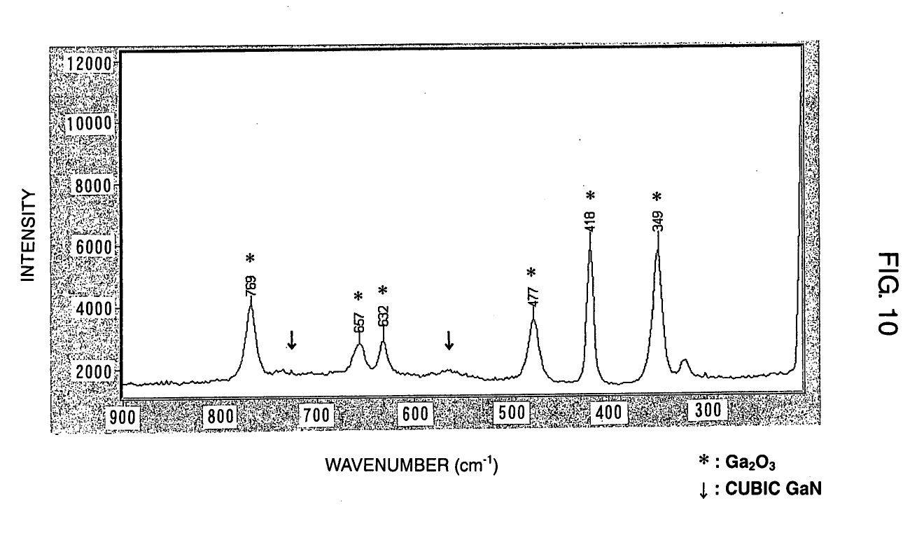

FIGS. 9 and 10 show results of Raman spectrum measurement of the gallium oxide single crystal composite having the gallium nitride film formed on its surface. Measurement was performed by using Renishaw System-3000 as a Raman spectrum measurement apparatus under conditions including an excited laser of Ar⁺ (514.5 nm), an irradiation intensity of about 1.0 mW, and an irradiation time of 90 sec. FIG. 9 shows a Raman spectrum of the substrate (i.e., gallium oxide single crystal composite) alone, and FIG. 10 shows a spectrum of the gallium nitride film. In comparison of the spectrum of FIG. 9 and the spectrum of FIG. 10, in the spectrum of FIG. 10, broad peaks at about 560 cm⁻¹ and about 730 cm⁻¹ were slightly detected. That is, those broad peaks correspond to cubic GaN. The peak at 560 cm⁻¹ correspond to TO mode, and the peak at 730 cm⁻¹ correspond to LO mode. Thus, the results indicate that the gallium nitride film grown on the surface of the gallium oxide single crystal composite contained cubic GaN. Note that peaks marked by “*” of FIGS. 9 and 10 represent peaks of Ga₂O₃ derived from the gallium oxide single crystal composite used as a substrate. The peaks marked by “↓” represent peaks of cubic GaN.

The results of the reflection high-energy electron diffraction, X-ray diffraction, and Raman spectrum measurement indicate that the gallium nitride film grown on the surface of the gallium oxide single crystal composite according to Examples of the present invention had a structure in which cubic c-GaN was dominant.

### INDUSTRIAL APPLICABILITY

The gallium oxide single crystal composite of the present invention has the gallium nitride layer formed of cubic gallium nitride on the surface of the gallium oxide single crystal, and thus can be used as a substrate used for forming a group III-V nitride semiconductor formed of gallium nitride (GaN), aluminum nitride (AlN), indium nitride (InN), a mixed crystal thereof, or the like. The nitride semiconductor film to be obtained is a high quality cubic nitride semiconductor film in which mixing of a hexagonal crystal structure is reduced as much as possible. In particular, the gallium oxide single crystal composition of the present invention is suitable for growth of a cubic GaN film because lattice mismatch between the substrate and an epitaxial layer is reduced as much as possible. The gallium oxide single crystal composition of the present invention exhibits excellent effects even in the case where the gallium oxide single crystal composition is used for an ultrahigh-frequency/high-output operating transistor substrate which is indispensable for next generation electronics, a substrate for an optical device which is expected as a next generation nitride semiconductor laser such as a blue surface emitting laser or a blue quantum dot laser, and the like.

The process for producing a gallium oxide single crystal composite of the present invention requires advantageous conditions compared with conditions required for obtaining a bulk gallium nitride single crystal and can be advantageously produced industrially because the gallium oxide single crystal composite having the gallium nitride layer formed of cubic gallium nitride on the surface of the gallium oxide single crystal can be obtained by simple means and by using the gallium oxide single crystal available with relative ease.

1. A gallium oxide single crystal composite, characterized by comprising a gallium nitride layer formed of cubic gallium nitride (GaN) on a surface of a gallium oxide (Ga₂O₃) single crystal.

2. A gallium oxide single crystal composite according to claim 1, wherein the gallium nitride layer comprises cubic gallium nitride in substantially <100> orientation.

3. A gallium oxide single crystal composite according to claim 1, wherein the gallium nitride layer has a thickness of 1 nm or more.

4. A gallium oxide single crystal composite according to claim 1, wherein the gallium nitride layer is formed on the surface of the gallium oxide single crystal through nitriding treatment employing ECR plasma or RF plasma.

5. A gallium oxide single crystal composite according to claim 1, wherein the surface of the gallium oxide single crystal comprises a (100) plane of the gallium oxide single crystal.

6. A gallium oxide single crystal composite according to claim 1, wherein the gallium oxide single crystal composite is used as a nitride semiconductor substrate used for forming a nitride semiconductor.

7. A process for producing a gallium oxide single crystal composite, characterized by comprising subjecting a surface of a gallium oxide (Ga₂O₃) single crystal to nitriding treatment employing ECR plasma or RF plasma to form a gallium nitride layer formed of cubic gallium nitride (GaN) on the surface of the gallium oxide single crystal.

8. A process for producing a gallium oxide single crystal composite according to claim 7, comprising polishing the surface of the gallium oxide single crystal before the nitriding treatment.

9. A process for producing a gallium oxide single crystal composite according to claim 8, wherein means for polishing the surface of the gallium oxide single crystal comprises chemical mechanical polishing.

10. A process for producing a gallium oxide single crystal composite according to claim 7, comprising:
subjecting the surface of the gallium oxide single crystal to surface treatment; and
heating the surface-treated gallium oxide single crystal for thermal cleaning treatment before the nitriding treatment.

11. A process for producing a gallium oxide single crystal composite according to claim 10, wherein the surface treatment comprises HF treatment using hydrogen fluoride (HF) and/or etchant treatment using a solution prepared by mixing H₂O, H₂SO₄, and H₂O₂ in a volume ratio of H₂O:H₂SO₄:H₂O₂=1:(3 to 4):1.

12. A process for producing a gallium oxide single crystal composite according to claim 7, wherein the surface of the gallium oxide single crystal comprises a (100) plane of the gallium oxide single crystal.

13. A process for producing a nitride semiconductor film, characterized by comprising growing a nitride semiconductor film on a surface of the gallium oxide single crystal composite according to claim 1 by an RF-MBE method.

14. A process for producing a nitride semiconductor film according to claim 13, wherein the nitride semiconductor film is grown by using a nitrogen (N₂) gas.

15. A process for producing a nitride semiconductor film according to claim 13, wherein the nitride semiconductor film comprises a gallium nitride film.

16. A gallium oxide single crystal composite according to claim 2, wherein the gallium nitride layer is formed on the surface of the gallium oxide single crystal through nitriding treatment employing ECR plasma or RF plasma.

17. A gallium oxide single crystal composite according to claim 2, wherein the surface of the gallium oxide single crystal comprises a (100) plane of the gallium oxide single crystal.

18. A gallium oxide single crystal composite according to claim 2, wherein the gallium oxide single crystal composite is used as a nitride semiconductor substrate used for forming a nitride semiconductor.

19. A process for producing a gallium oxide single crystal composite according to claim 8, wherein the surface of the gallium oxide single crystal comprises a (100) plane of the gallium oxide single crystal.

20. A process for producing a nitride semiconductor film, characterized by comprising growing a nitride semiconductor film on a surface of the gallium oxide single crystal composite according to claim 2 by an RF-MBE method.
